(19) United States
(12) Patent Application Publication
(10) Pub. No.: US 2014/0070193 A1
(43) Pub. Date: Mar. 13, 2014

(54) TRANSISTOR, METHOD OF MANUFACTURING TRANSISTOR, METHOD OF MANUFACTURING SEMICONDUCTOR UNIT, AND METHOD OF MANUFACTURING DISPLAY UNIT

(71) Applicant: Sony Corporation, Tokyo (JP)

(72) Inventors: Akihiro Nomoto, Kanagawa (JP); Mao Katsuhara, Kanagawa (JP); Kenichi Kurihara, Kanagawa (JP)

(73) Assignee: Sony Corporation, Tokyo (JP)

(21) Appl. No.: 14/017,791

(22) Filed: Sep. 4, 2013

(30) Foreign Application Priority Data
Sep. 11, 2012 (JP) 2012-199098

(51) Int. Cl. H01L 51/05

(52) U.S. Cl. CPC H01L 51/0512
USPC 257/40; 257/347; 438/34; 438/151

(57) ABSTRACT

A method of manufacturing a transistor includes: forming a gate electrode; forming a laminated film of an organic insulating film and an organic semiconductor film with a gate insulating film therebetween, the laminated film being opposed to the gate electrode; and patterning the organic semiconductor film.

### BACKGROUND

The present technology relates to a transistor including an organic semiconductor film and an organic insulating film, a method of manufacturing the transistor, a method of manufacturing a semiconductor unit, and a method of manufacturing a display unit.

Thin film transistors (TFTs) each includes a substrate, and a gate electrode, a gate insulating film, a semiconductor film, and source/drain electrodes on the substrate, which are used as drive devices for a variety of electronic apparatuses such as display units. While a semiconductor film of such a TFT is configured of an inorganic material or an organic material, a semiconductor film configured of the organic material (organic semiconductor film) is recently promising in light of cost and flexibility (for example, see Japanese Unexamined Patent Application Publication Nos. 2011-77470 and 2011-187626).

### SUMMARY

It is desired for a TFT including the above-described organic semiconductor film to decrease manufacturing defects and improve a production yield thereby.

It is desirable to provide a transistor capable of being manufactured at a high production yield, a method of manufacturing the transistor, a method of manufacturing a semiconductor unit, and a method of manufacturing a display unit.

According to an embodiment of the present technology, there is provided a transistor including: a gate electrode; a gate insulating film; an organic semiconductor film opposed to the gate electrode with a gate insulating film therebetween; and an organic insulating film being in contact with one surface of the organic semiconductor film, and extending wider than the organic semiconductor film.

According to an embodiment of the present technology, there is provided a method of manufacturing a transistor, including: forming a gate electrode; forming a laminated film of an organic insulating film and an organic semiconductor film with a gate insulating film therebetween, the laminated film being opposed to the gate electrode; and patterning the organic semiconductor film.

According to an embodiment of the present technology, there is provided a method of manufacturing a semiconductor unit, including: forming a plurality of transistors on a substrate, wherein the formation of each of the transistors includes forming a gate electrode, forming a laminated film of an organic insulating film and an organic semiconductor film with a gate insulating film therebetween, the laminated film being opposed to the gate electrode, and patterning the organic semiconductor film.

According to an embodiment of the present technology, there is provided a method of manufacturing a display unit, including: forming a transistor that drives a display device, wherein the formation of each of the transistors includes forming a gate electrode, forming a laminated film of an organic insulating film and an organic semiconductor film with a gate insulating film therebetween, the laminated film being opposed to the gate electrode, and patterning the organic semiconductor film.

In the transistor or the method of manufacturing the transistor according to the above-described respective embodiments of the present technology, the organic insulating film extends with a predetermined thickness without being patterned. As a result, a difference in level in the transistor is decreased by a level corresponding to the thickness of the organic insulating film compared with a case where the organic insulating film is patterned together with the organic semiconductor film.

According to the transistor, the method of manufacturing the transistor, the method of manufacturing the semiconductor unit, and the method of manufacturing the display unit of the above-described respective embodiments of the present technology, a difference in level in a transistor is decreased, which suppresses occurrence of film separation and disconnection etc., caused by such a difference in level, leading to high-yield production.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a sectional diagram illustrating a configuration of a transistor according to an embodiment of the present technology.

FIG. 2A is a sectional diagram illustrating a manufacturing process of the transistor illustrated in FIG. 1.

FIG. 2B is a sectional diagram illustrating a step following FIG. 2A.

FIG. 2C is a sectional diagram illustrating a step following FIG. 2B.

FIG. 3A is a sectional diagram illustrating an exemplary manufacturing process of a plurality of transistors.

FIG. 3B is a plan diagram of a substrate illustrated in FIG. 3A.

FIG. 4A is a sectional diagram illustrating a step following FIG. 2C.

FIG. 4B is a sectional diagram illustrating a step following FIG. 4A.

FIG. 5 is a sectional diagram illustrating a configuration of a transistor according to a comparative example.

FIG. 6 is a sectional diagram illustrating another example of the transistor illustrated in FIG. 5.

FIG. 7 is a diagram illustrating an overall configuration of a display unit including the transistor illustrated in FIG. 1.

FIG. 8A is an equivalent circuit diagram illustrating an example of a pixel drive circuit illustrated in FIG. 7.

FIG. 8B is an equivalent circuit diagram illustrating another example of the pixel drive circuit illustrated in FIG. 7.

FIG. 9 is a sectional diagram illustrating a configuration of an end section of the display unit illustrated in FIG. 7.

FIG. 10A is a perspective diagram illustrating an example of appearance of application example 1.

FIG. 10B is a perspective diagram illustrating another example of appearance of the application example 1.

FIG. 11 is a perspective diagram illustrating appearance of application example 2.

FIG. 12 is a perspective diagram illustrating appearance of application example 3.

FIG. 13A is a perspective diagram illustrating appearance of application example 4 as viewed from the front thereof.

FIG. 13B is a perspective diagram illustrating appearance of the application example 4 as viewed from the back thereof.

FIG. 14 is a perspective diagram illustrating appearance of application example 5.

FIG. 15 is a perspective diagram illustrating appearance of application example 6.

FIG. 16A is a diagram illustrating application example 7 in a closed state thereof.

FIG. 16B is a diagram illustrating the application example 7 in an opened state thereof.

### DETAILED DESCRIPTION

Hereinafter, an embodiment of the present technology is described in detail with reference to the accompanying drawings.

### Embodiment

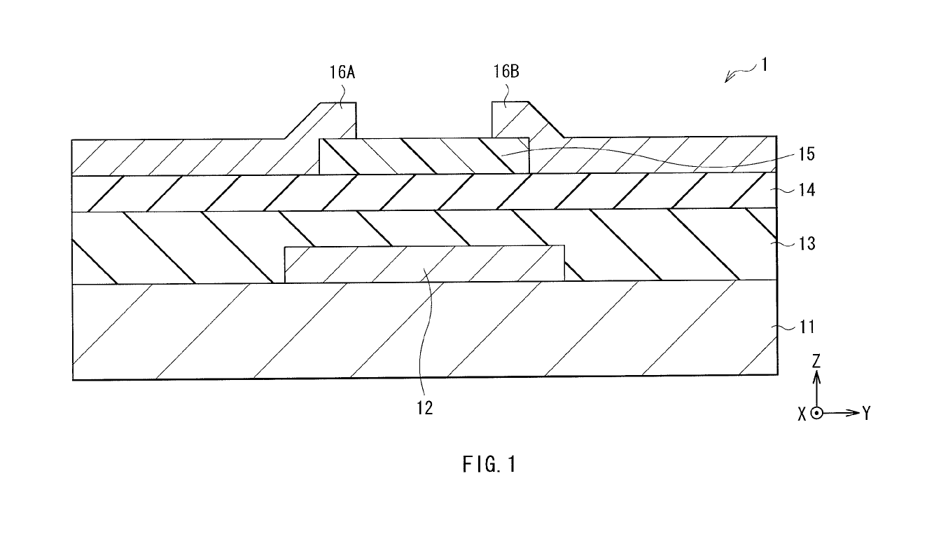

FIG. 1 illustrates a configuration of a transistor (transistor 1) according to an embodiment of the present technology. The transistor 1 is a field-effect transistor including an organic semiconductor material as a material for a semiconductor film, i.e., is an organic TFT, and, for example, may be used as a drive device for each of displays using liquid crystal, organic electroluminescence (EL), and an electrophoretic display element. The transistor 1, which is a TFT with a so-called top contact/bottom gate structure, includes a substrate 11, and includes a gate electrode 12, a gate insulating film 13, an organic insulating film 14, and an organic semiconductor film 15, and source/drain electrodes 16A and 16B in this order on the substrate 11.

The substrate 11 supports the gate electrode 12 etc., and has an insulative surface (on a side close to the gate electrode 12). The substrate 11 may be configured of, for example, a plastic substrate including polyethersulfone (PES), polyethylene naphthalate (PEN), polyethylene terephthalate (PET), polycarbonate (PC), and polyimide (PI). As the substrate 11, a metal foil such as a stainless steel (SUS) foil having a surface laminated with resin or a glass substrate may be used. The plastic substrate or the metal foil is preferably used to achieve high flexibility of the substrate. The substrate 11 may have a thickness (length in a Z direction) of, for example, about 20 nm to 1 mm.

The gate electrode 12 serves to apply a gate voltage to the transistor 1, and control carrier density in the organic semiconductor film 15 with the gate voltage. The gate electrode 12 is provided in a selective region on the substrate 11, and may be configured of, for example, single metal such as gold (Au), aluminum (Al), silver (Ag), copper (Cu), platinum (Pt), and nickel (Ni) or alloy thereof. The gate electrode 12 may be formed as a laminated body containing titanium (Ti) and/or chromium (Cr). Such a laminated structure improves adhesion of the gate electrode 12 to the substrate 11 or a resist for processing. As a material for the gate electrode 12, other materials such as inorganic conductive materials, organic conductive materials, and carbon materials may be used. The gate electrode 12 may have a thickness of, for example, about 50 nm to 200 nm.

The gate insulating film 13 isolates the gate electrode 12 from the organic semiconductor film 15 electrically connected to the source/drain electrodes 16A and 16B, and is provided, together with the organic insulating film 14, between the gate electrode 12 and the organic semiconductor film 15. The gate insulating film 13 may be configured of, for example, an organic insulating film 50 nm to 1000 nm in thickness including polyvinyl phenol (PVP), polymethylmethacrylate (PMMA), polyvinyl alcohol (PVA), or PI. The gate insulating film 13 may be configured of an inorganic insulating film including silicon oxide (SiO₂), aluminum oxide (Al₂O₃), tantalum oxide (Ta₂O₅), or silicon nitride (SiNx).

The organic insulating film 14 is in contact with one surface (bottom) of the organic semiconductor film 15, and extends over a region wider than the island-shaped organic semiconductor film 15, for example, over the entire surface of the substrate 11. In this way, the organic insulating film 14 in this embodiment is provided over the region wider than the organic semiconductor film 15, which reduces a difference in level in the transistor 1, as will be described in detail later. For example, the organic insulating film 14 may be formed together with the organic semiconductor film 15 through phase separation, and thus the organic insulating film 14 is tightly in contact with the organic semiconductor film 15. This reduces carrier trap at an interface between the organic insulating film 14 and the organic semiconductor film 15, resulting in improvement in characteristics of the transistor 1, for example, mobility and subthreshold characteristics (S value). Moreover, this enables selection of a constituent material for the gate insulating film 13 without considering an interface with (adhesion to) the organic semiconductor film 15. The organic insulating film 14 may be configured of, for example, a film of poly(α-methylstyrene) (PaMS) (CYTOP (registered trademark), from Asahi Glass co., or TOPAS (registered trademark), from ADVANCED POLYMERS GmbH) having a thickness of 1 nm to 1000 nm both inclusive.

The organic semiconductor film 15 is provided on the organic insulating film 14 in opposition to the gate electrode 12, and forms channels in response to a gate voltage applied thereto. The organic semiconductor film 15 may be configured of either of a p-type organic semiconductor material and an n-type organic semiconductor material. As a material for the organic semiconductor film 15, for example, acene series semiconductors such as pentacene, peri-xanthenoxanthene derivatives, and poly(3-hexylthiophene-2,5-diyl) (P3HT) may be used. The organic semiconductor film 15 may have a thickness of, for example, about 1 nm to 1000 nm.

A pair of source/drain electrodes 16A and 16B, which are electrically connected to the organic semiconductor film 15, are provided covering the organic insulating film 14 from the surface of the organic semiconductor film 15 along the side faces thereof. Specifically, the source/drain electrodes 16A and 16B cover a difference in level having a step height corresponding to the thickness of the organic semiconductor film 15. The source/drain electrodes 16A and 16B may be configured of a material having a thickness of 50 nm to 200 nm both inclusive, the material including, for example, single metal such as gold, aluminum, silver, copper, platinum, and nickel, alloy thereof, and indium-tin oxide (ITO). As with the gate electrode 12, the source/drain electrodes 16A and 16B may each also be laminated with titanium or chromium over a top or bottom thereof. The source/drain electrodes 16A and 16B may be formed by patterning a conductive ink containing conductive fine particles.

For example, such a transistor 1 may be manufactured in the following way.

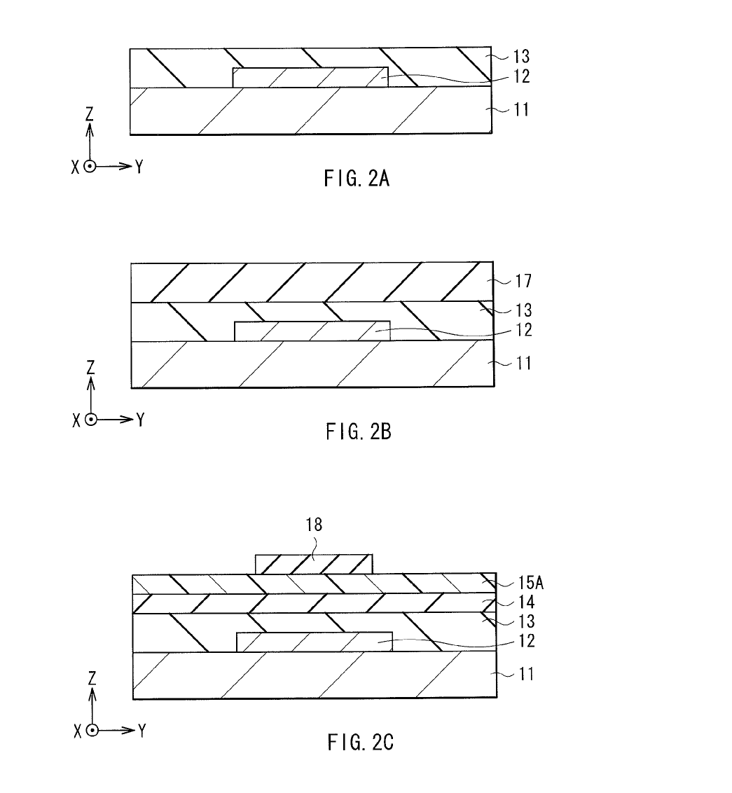

First, as illustrated in FIG. 2A, the gate electrode 12 and the gate insulating film 13 are formed in this order on the substrate 11. Specifically, first, a conductive film to be the gate electrode 12 is formed on the entire surface of the substrate 11 by, for example, an evaporation process or a sputter process, and then a photoresist is formed and patterned on the conductive film by, for example, a photolithography process. Then, the conductive film is etched to be patterned with the use of such a patterned photoresist as a mask. Consequently, the gate electrode 12 is formed. Alternatively, the gate electrode 12 may be formed by a printing process including screen printing, gravure printing, and inkjet printing. Then, the gate insulating film 13 including an organic insulating material is formed over the entire substrate 11 by, for example, a coating process such as a spin coating process or a printing process including screen printing, gravure printing, and inkjet printing. In the case where the gate insulating film 13 is formed of an inorganic insulating material, the gate insulating film 13 may be formed by, for example, an evaporation process, a sputter process, or a chemical vapor deposition (CVD) process.

After the gate insulating film 13 is provided, the organic insulating film 14 and an organic semiconductor film 15A are formed on the gate insulating film 13 through, for example, phase separation (FIG. 2C shown later). In detail, first, a mixed solution 17 is prepared by dissolving respective constituent materials for the organic insulating film 14 and the organic semiconductor film 15, for example, PaMS and 3,9-bis(p-ethylphenyl)peri-xanthenoxanthene (C2PXX), are dissolved in a solvent A such as toluene, and the mixed solution 17 is applied onto the gate insulating film 13 by a spin coating process (FIG. 2B). The used solvent A dissolves the respective constituent materials for the organic insulating film 14 and the organic semiconductor film 15, but does not dissolve the mask (a protective film 18 in FIG. 2C shown later) for patterning of the organic semiconductor film 15A. Such an undissolved state includes not only a completely undissolved state but also a state where a small amount of material is dissolved, which however has almost no influence on the thickness of the material. Then, the mixed solution 17 is dried by baking, thereby the organic semiconductor material and the organic insulating material are separated from each other. This results in formation of the organic semiconductor film 15A as an upper layer and the organic insulating film 14 as a lower layer (formation of a laminated film). Specifically, at this time, the organic semiconductor film 15A has the same planar shape as that of the organic insulating film 14. Use of such phase separation makes it possible to collectively form the organic insulating film 14 and the organic semiconductor film 15A in one film formation step.

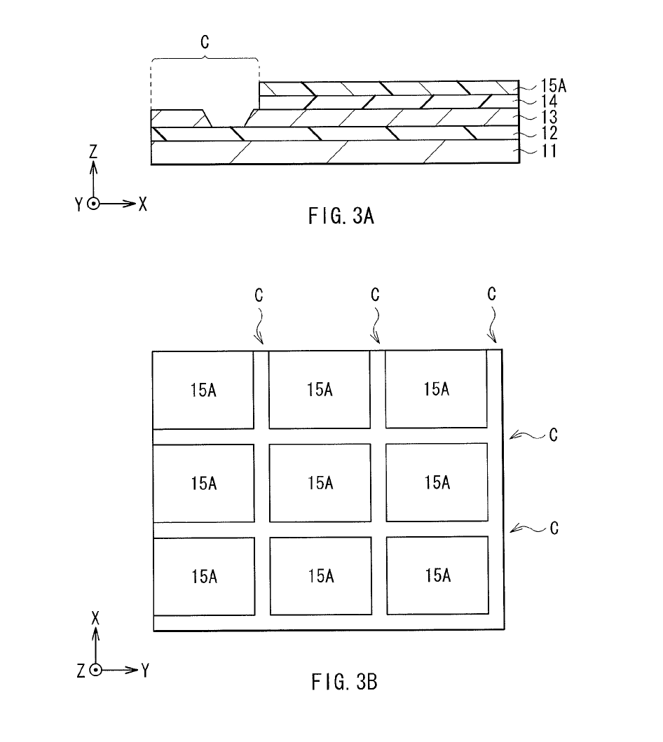

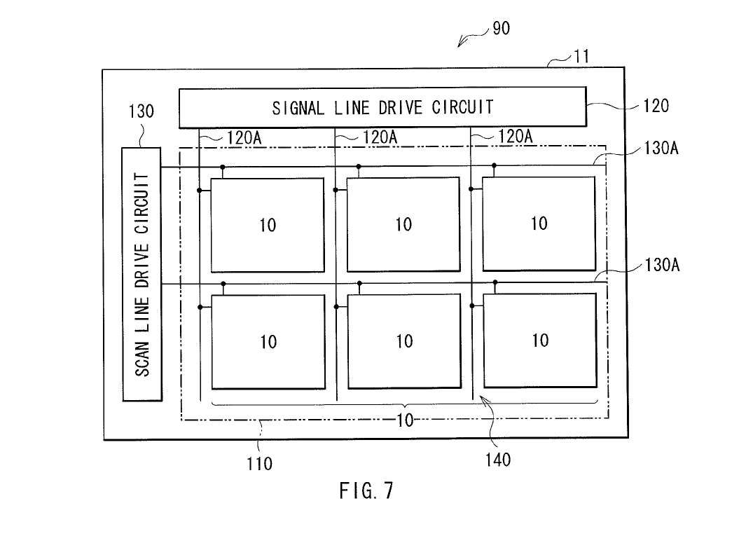

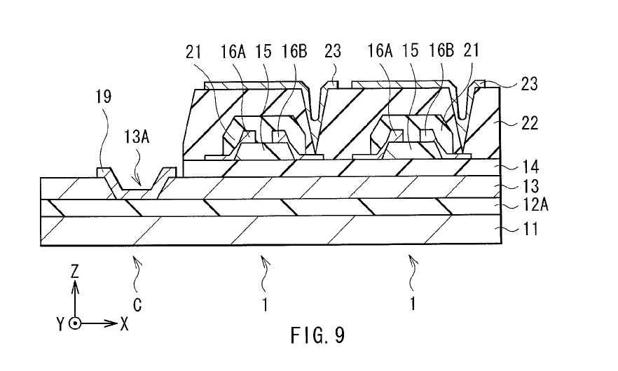

In the case where a semiconductor unit including a plurality of transistors 1 (for example, a display unit 90 in FIG. 7 shown later) is manufactured, it is preferable that a lead-out section C be locally provided on the substrate 11 as illustrated in FIGS. 3A and 3B. The lead-out section C corresponds to a region having no organic insulating film 14 therein. For example, the mixed solution 17 may not be applied onto the lead-out section C. The lead-out section C may be formed by partially removing the organic insulating film 14 after the mixed solution 17 is applied onto the entire surface of the substrate 11. For example, a lead-out electrode (lead-out electrode 19 in FIG. 9 shown later) may be formed in the lead-out section C. For example, the lead-out section C may be disposed outside (for example, on two sides of) a display region having a plurality of transistors 1 therein (a display region 110 in FIG. 7 shown later). In the case where a plurality of display regions are provided in one substrate 11, the lead-out section C is provided outside each display region (FIG. 3B).

After the organic insulating film 14 and the organic semiconductor film 15A are formed, as illustrated in FIG. 2C, the protective film 18 including polyvinyl alcohol (PVA) is formed on the organic semiconductor film 15A by, for example, a printing process. The protective film 18 is patterned into a desired shape so as to be used as a mask as described above.

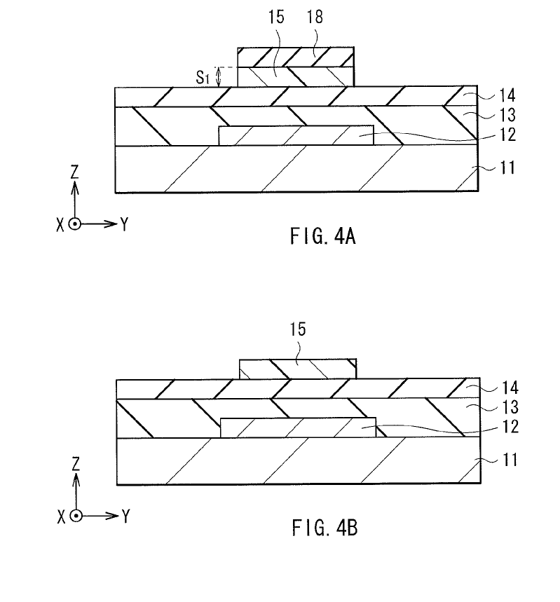

Then, only the organic semiconductor film 15A in a portion exposed from the protective film 18 is selectively dissolved using a solvent B such as, for example, isopropyl alcohol (IPA) to form the organic semiconductor film 15 having the same planar shape as that of the protective film 18 (FIG. 4A). The used solvent B dissolves the constituent material for the organic semiconductor film 15 (organic semiconductor film 15A), but does not dissolve the protective film 18 and the organic insulating film 14. In this exemplary case, only the organic semiconductor film 15 (organic semiconductor film 15A) is selectively patterned as above, thereby making it possible to improve a production yield through decreasing a difference in level (difference in level S₁) formed in the transistor. This will be described in detail below.

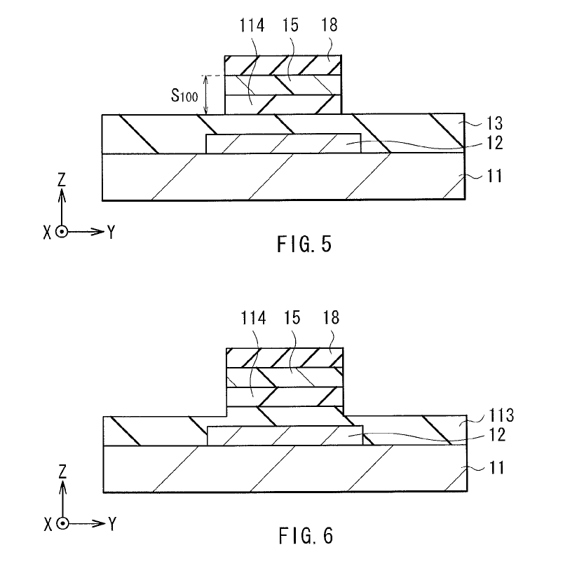

When the organic insulating film is patterned together with the organic semiconductor film, a difference in level (difference in level S₁₀₀) is formed on the gate insulating film 13. The difference in level has a step height corresponding to the total thickness of an organic insulating film 114 and the organic semiconductor film 15 as illustrated in FIG. 5. Such a large difference in level S₁₀₀ causes film separation and/or disconnection of a wiring etc. formed as an upper layer, leading to a reduction in production yield. For example, in a transistor with a top contact structure, the source/drain electrodes may cover a portion of the difference in level S₁₀₀, and therefore disconnection may occur in the source/drain electrodes. In addition, patterning of the organic insulating film may result in excessive etching that causes shaving of the organic insulating film 114 and a gate insulating film 113 near the organic semiconductor film 15, which may disturb sufficient maintenance of isolation. In a transistor with a bottom gate structure, gate leakage increases with a decrease in thickness of the gate insulating film 113.

In a possible approach for decreasing a difference in level, the organic semiconductor film 15A is not removed. In such a case, however, a leakage current may occur through the organic semiconductor film 15A.

In contrast, in the transistor 1, only the organic semiconductor film 15A is selectively dissolved (patterned) with the solvent B; hence, the organic insulating film 14 remains without being patterned. This results in formation of a difference in level S₁ in the transistor 1, the difference in level S₁ corresponding to a height from the organic insulating film 14 to the organic semiconductor film 15, i.e., having a step height corresponding to the thickness of the organic semiconductor film 15. As compared to the difference in level S₁₀₀ (FIG. 5), the difference in level S₁ is reduced by a level corresponding to the thickness of the organic insulating film, leading to improvement in production yield. Moreover, the organic insulating film 14 exists over a wide region between the gate insulating film 13 (gate electrode 12) and the organic semiconductor film 15, and thus sufficient isolation is maintained. In particular, this prevents disconnection of the source/drain electrodes 16A and 16B and gate leakage in the transistor 1 with a bottom-gate/top-contact structure.

After the organic semiconductor film 15 is formed, only the protective film 18 is selectively dissolved with, for example, a solvent C such as water, and is removed from the surface of the organic semiconductor film 15 (FIG. 4B). The used solvent C dissolves the constituent material for the protective film 18, but does not dissolve the organic semiconductor film 15 and the organic insulating film 14. Then, a metal film is formed on the organic semiconductor film 15 and the organic insulating film 14, and then the metal film is patterned to form the source/drain electrodes 16A and 16B. The transistor 1 is completed through the above steps.

In the transistor 1 of this embodiment, when a predetermined potential is supplied to the gate electrode 12, an electric filed is generated between channels of the organic semiconductor film 15, and thus a current flows between the source/drain electrodes 16A and 16B, and consequently the transistor 1 serves as a so-called field-effect transistor. In this exemplary case, the organic semiconductor film 15A is selectively dissolved with the solvent B to be patterned while the organic insulating film 14 is not dissolved, thereby a smaller difference in level is formed in the transistor 1.

As described above, in this embodiment, only the organic semiconductor film 15A is patterned while the organic insulating film 14 is not patterned, which suppresses occurrence of film separation and/or disconnection of the wiring layer as an upper layer, thereby making it possible to improve a production yield.

### APPLICATION EXAMPLES

FIG. 7 illustrates an overall configuration of a display unit (display unit 90) including the transistor 1 as a drive device. Examples of the display unit 90 include a liquid crystal display, an organic EL display, and an electronic paper display, where a plurality of display devices 10 arranged in a matrix and various drive circuits that drive the display devices 10 are provided in the display region 110 on the substrate 11. For example, a signal line drive circuit 120 and a scan line drive circuit 130 as drivers for image display and a pixel drive circuit 140 may be provided as the drive circuits on the substrate 11. A not-illustrated sealing panel is attached to the substrate 11, and the above-described drive circuits and a display layer (not shown) are sealed with the sealing panel.

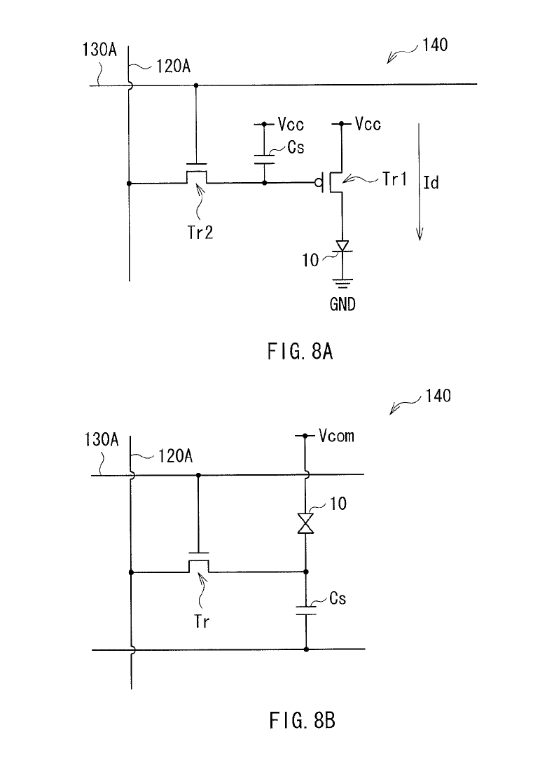

FIG. 8A is a circuit diagram of the pixel drive circuit 140. The pixel drive circuit 140 is an active drive circuit having one or both of transistors Tr1 and Tr2 as the transistor 1. A capacitor Cs is provided between the transistors Tr1 and Tr2, and the display device 10 is connected in series to the transistor Tr1 between a first power line (Vcc) and a second power line (GND). In such a pixel drive circuit 140, a plurality of signal lines 120A are disposed in a column direction, and a plurality of scan lines 130A are disposed in a row direction. Each signal line 120A is connected to the signal line drive circuit 120, and an image signal is supplied from the signal line drive circuit 120 to the source electrode of the transistor Tr2 through the signal line 120A. Each scan line 130A is connected to the scan line drive circuit 130, and scan signals are sequentially supplied from the scan line drive circuit 130 to the gate electrode of the transistor Tr2 through the scan line 130A. As illustrated in FIG. 8B, only the transistor Tr1 may be used as the transistor in the pixel drive circuit 140. In the display unit 90, the transistors Tr1 and Tr2 are each configured of the transistor 1 of the above-described embodiment. This results in a high production yield of the display unit 90 and good TFT characteristics of each of the transistors Tr1 and Tr2, and consequently high quality display is achieved.

FIG. 9 illustrates part of a sectional configuration of an end section of the substrate 11. The display unit 90 includes the transistor 1, and includes a protective film 21 and an interlayer insulating film 22 in this order on the transistor 1. A pixel electrode 23 is disposed on the interlayer insulating film 22 for each of the display devices 10. For example, a liquid crystal layer, an organic electroluminescence (EL) layer, an inorganic EL layer, or an electrophoretic display element (display layer) may be provided between the pixel electrode 23 and a common electrode (not shown). In the lead-out section C, the lead-out electrode 19 is electrically connected to a gate wiring 12A through a connection hole 13A in the gate insulating film 13. The gate wiring 12A may be a wiring connected to the gate electrode 12, i.e., for example, the scan line 130A (FIGS. 8A and 8B). The lead-out electrode 19 may be connected to an integrated circuit (IC) by, for example, a tape-automated bonding (TAB) method. Such a display unit 90 may be mounted in each of electronic apparatuses shown in the following application examples 1 to 7, for example.

### Application Example 1

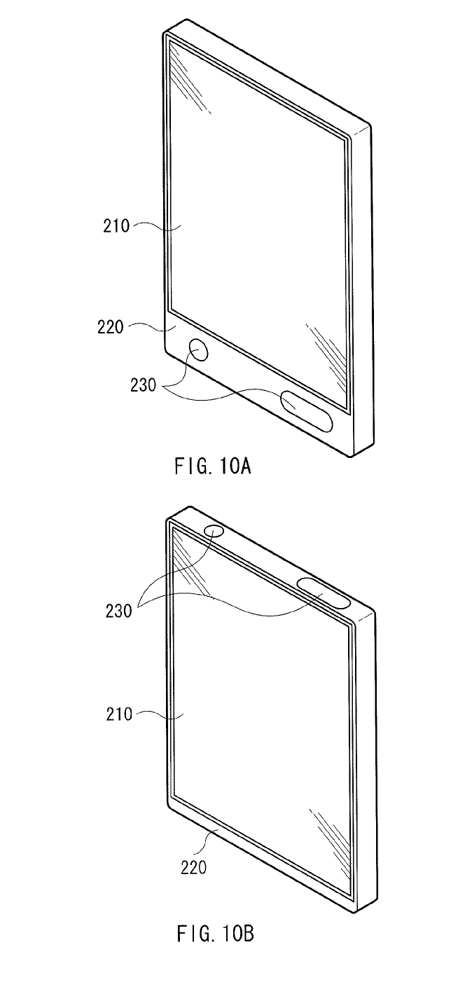

FIGS. 10A and 10B illustrate appearance of an electronic book reader. The electronic book reader may include, for example, a display section 210 and a non-display section 220 having an operational section 230. The display section 210 is configured of the above-described display unit 90. The operational section 230 may be provided on the same surface (front surface) as the surface of the display section 210 as illustrated in FIG. 10A, or may be provided on a surface (top surface) different from the surface of the display section 210 as illustrated in FIG. 10B.

### Application Example 2

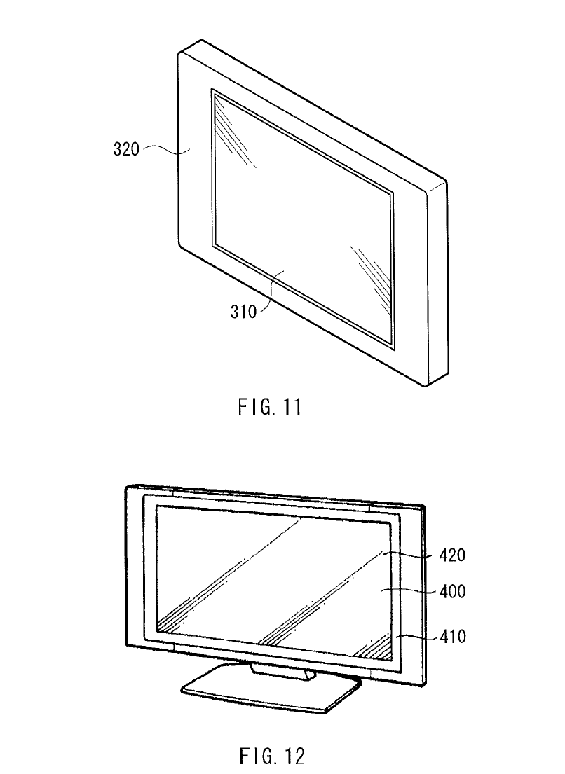

FIG. 11 illustrates appearance of a tablet personal computer. The tablet personal computer may include, for example, a touch panel section 310 and a housing 320, where the touch panel section 310 is configured of the above-described display unit 90.

### Application Example 3

FIG. 12 illustrates appearance of a television unit. The television unit may include, for example, an image display screen section 400 including a front panel 410 and filter glass 420, where the image display screen section 400 is configured of the above-described display unit 90.

### Application Example 4

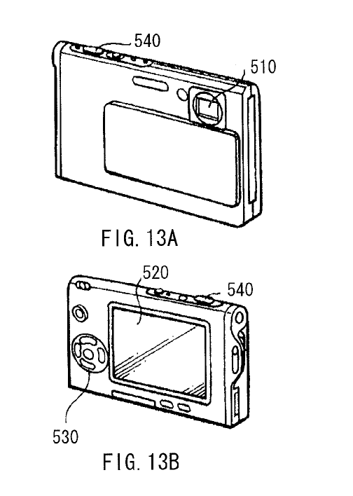

FIGS. 13A and 13B illustrate appearance of a digital still camera. The digital still camera may include, for example, a light emitting section 510 for flash, a display section 520, a menu switch 530, and a shutter button 540, where the display section 520 is configured of the above-described display unit 90.

### Application Example 5

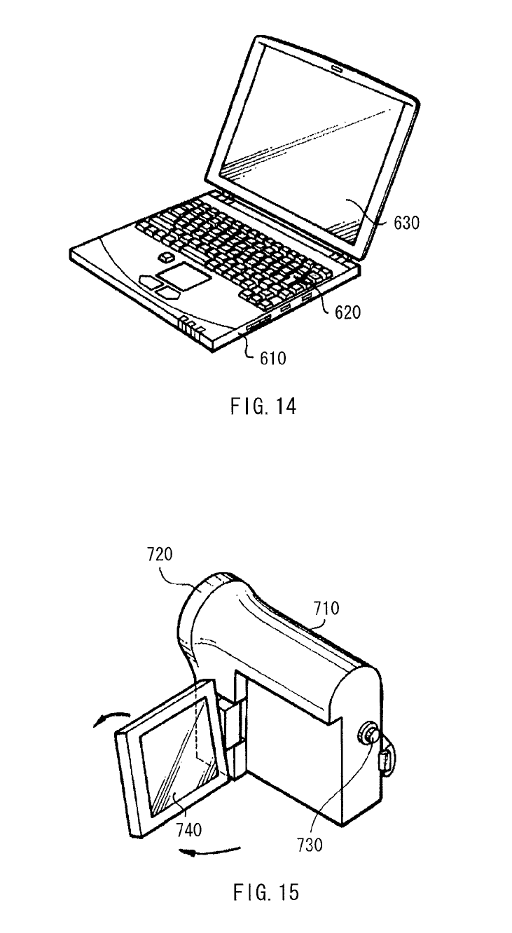

FIG. 14 illustrates appearance of a notebook personal computer. The notebook personal computer may include, for example, a main body 610, a keyboard 620 for input operation of characters etc., and a display section 630 that displays images, where the display section 630 is configured of the above-described display unit 90.

### Application Example 6

FIG. 15 illustrates appearance of a video camera. The video camera may include, for example, a main body section 710, an object-shooting lens 720 provided on a front side face of the main body section 710, a start-and-stop switch 730 for shooting, and a display section 740, where the display section 740 is configured of the above-described display unit 90.

### Application Example 7

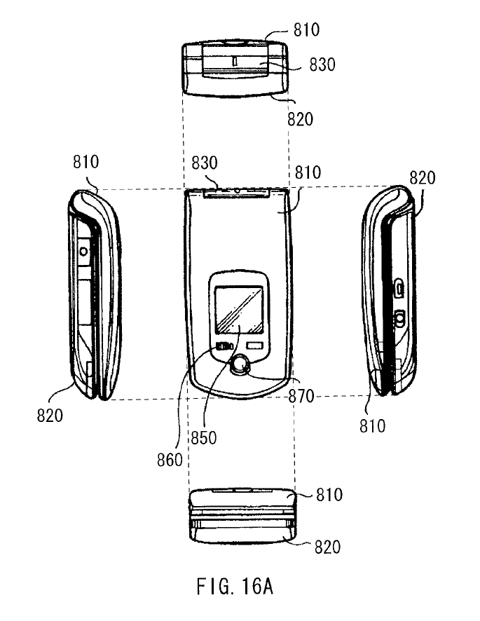

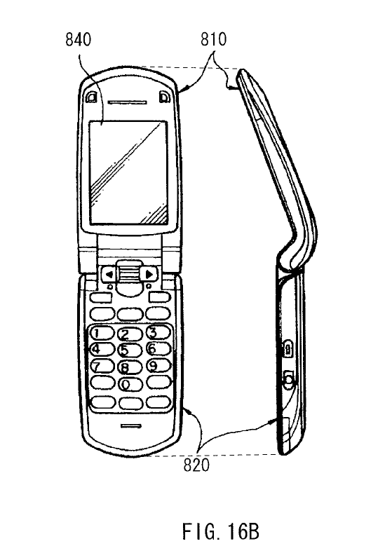

FIGS. 16A and 16B illustrate appearance of a mobile phone. For example, the mobile phone may be configured of an upper housing 810 and a lower housing 820 connected to each other by a hinge section 830, and may include a display 840, a sub-display 850, a picture light 860, and a camera 870, where one or both of the display 840 and the sub-display 850 is configured of the above-described display unit 90.

Although the present technology has been described with reference to the example embodiment and the application examples hereinbefore, the technology is not limited thereto, and various modifications or alterations thereof may be made. For example, although the bottom-gate/top-contact transistor 1 has been described in the above-described example embodiment and application examples, the present technology may be applied to a bottom-gate/bottom-contact transistor, a top-gate/top-contact transistor, or a top-gate/bottom-contact transistor.

Moreover, although the above-described example embodiment and application examples have been described with a case where the organic insulating film 14 is provided over substantially the entire surface (the surface region excluding the lead-out section C) of the substrate 11, the organic insulating film 14 may be divided at each of boundaries between the adjacent transistors 1 as long as the organic insulating film 14 extends wider than the organic semiconductor film 15 and surrounds the organic semiconductor film 15.

Furthermore, for example, while the material and the thickness of each layer, and the deposition process and the deposition condition of each layer have been described in the above-described example embodiment and application examples, these are not limitative. In other words, other materials and thicknesses may be used, or other deposition processes and deposition conditions may be used.

It is possible to achieve at least the following configurations from the above-described example embodiment of the disclosure.
(1) A method of manufacturing a transistor, including:

forming a gate electrode;

forming a laminated film of an organic insulating film and an organic semiconductor film with a gate insulating film therebetween, the laminated film being opposed to the gate electrode; and

patterning the organic semiconductor film.
(2) The method of manufacturing the transistor according to (1), wherein the organic semiconductor film is selectively dissolved to be patterned while the organic insulating film is not dissolved.
(3) The method of manufacturing the transistor according to (2), wherein a protective film is provided on the organic semiconductor film, and then the organic semiconductor film is patterned to have the same planar shape as that of the protective film.
(4) The method of manufacturing the transistor according to (3), wherein after the organic semiconductor film is patterned,

the protective film is selectively dissolved and removed.
(5) The method of manufacturing the transistor according to any one of (1) to (4), wherein the organic semiconductor film is formed to contact with the organic insulating film.
(6) The method of manufacturing the transistor according to any one of (1) to (5), wherein the organic insulating film and the organic semiconductor film are formed through phase separation from a mixed solution including respective constituent materials for the organic insulating film and the organic semiconductor film.
(7) The method of manufacturing the transistor according to any one of (1) to (6), further including:

electrically connecting source/drain electrodes to the organic semiconductor film.
(8) The method of manufacturing the transistor according to (7), wherein

the gate electrode, the gate insulating film, the organic insulating film, and the organic semiconductor film are provided in this order from a side close to a substrate, and

after the organic semiconductor film is patterned, the source/drain electrodes are formed.
(9) A method of manufacturing a semiconductor unit, including:

forming a plurality of transistors on a substrate,

wherein the formation of each of the transistors includes

forming a gate electrode,

forming a laminated film of an organic insulating film and an organic semiconductor film with a gate insulating film therebetween, the laminated film being opposed to the gate electrode, and

patterning the organic semiconductor film.
(10) The method of manufacturing the semiconductor unit according to (9), wherein a region that does not have the organic insulating film therein is locally provided on the substrate.
(11) The method of manufacturing the semiconductor unit according to (10), wherein the gate electrode is electrically connected to a lead-out electrode in the region having no organic insulating film therein.
(12) The method of manufacturing the semiconductor unit according to (10) or (11), wherein the region having no organic insulating film therein is provided outside a region having the plurality of transistors therein.
(13) A method of manufacturing a display unit, including:

forming a transistor that drives a display device,

wherein the formation of each of the transistors includes

forming a gate electrode,

forming a laminated film of an organic insulating film and an organic semiconductor film with a gate insulating film therebetween, the laminated film being opposed to the gate electrode, and

patterning the organic semiconductor film.
(14) A transistor, including:

a gate electrode;

a gate insulating film;

an organic semiconductor film opposed to the gate electrode with a gate insulating film therebetween; and

an organic insulating film being in contact with one surface of the organic semiconductor film, and extending wider than the organic semiconductor film.

The present disclosure contains subject matter related to that disclosed in Japanese Priority Patent Application JP 2012-199098 filed in the Japan Patent Office on Sep. 11, 2012, the entire content of which is hereby incorporated by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A method of manufacturing a transistor, comprising:
forming a gate electrode;
forming a laminated film of an organic insulating film and an organic semiconductor film with a gate insulating film therebetween, the laminated film being opposed to the gate electrode; and
patterning the organic semiconductor film.

2. The method of manufacturing the transistor according to claim 1, wherein the organic semiconductor film is selectively dissolved to be patterned while the organic insulating film is not dissolved.

3. The method of manufacturing the transistor according to claim 2, wherein a protective film is provided on the organic semiconductor film, and then
the organic semiconductor film is patterned to have the same planar shape as that of the protective film.

4. The method of manufacturing the transistor according to claim 3, wherein after the organic semiconductor film is patterned,
the protective film is selectively dissolved and removed.

5. The method of manufacturing the transistor according to claim 1, wherein the organic semiconductor film is formed to contact with the organic insulating film.

6. The method of manufacturing the transistor according to claim 1, wherein the organic insulating film and the organic semiconductor film are formed through phase separation from a mixed solution including respective constituent materials for the organic insulating film and the organic semiconductor film.

7. The method of manufacturing the transistor according to claim 1, further comprising:
electrically connecting source/drain electrodes to the organic semiconductor film.

8. The method of manufacturing the transistor according to claim 7, wherein
the gate electrode, the gate insulating film, the organic insulating film, and the organic semiconductor film are provided in this order from a side close to a substrate, and
after the organic semiconductor film is patterned, the source/drain electrodes are formed.

9. A method of manufacturing a semiconductor unit, comprising:
forming a plurality of transistors on a substrate,
wherein the formation of each of the transistors includes
forming a gate electrode,
forming a laminated film of an organic insulating film and an organic semiconductor film with a gate insulating film therebetween, the laminated film being opposed to the gate electrode, and
patterning the organic semiconductor film.

10. The method of manufacturing the semiconductor unit according to claim 9, wherein a region that does not have the organic insulating film therein is locally provided on the substrate.

11. The method of manufacturing the semiconductor unit according to claim 10, wherein the gate electrode is electrically connected to a lead-out electrode in the region having no organic insulating film therein.

12. The method of manufacturing the semiconductor unit according to claim 10, wherein the region having no organic insulating film therein is provided outside a region having the plurality of transistors therein.

13. A method of manufacturing a display unit, comprising:
forming a transistor that drives a display device,
wherein the formation of each of the transistors includes
forming a gate electrode,
forming a laminated film of an organic insulating film and an organic semiconductor film with a gate insulating film therebetween, the laminated film being opposed to the gate electrode, and
patterning the organic semiconductor film.

14. A transistor, comprising:
a gate electrode;
a gate insulating film;
an organic semiconductor film opposed to the gate electrode with a gate insulating film therebetween; and
an organic insulating film being in contact with one surface of the organic semiconductor film, and extending wider than the organic semiconductor film.
